(19) United States
(12) Patent Application Publication
(10) Pub. No.: US 2015/0158184 A1
(43) Pub. Date: Jun. 11, 2015

(54) PIEZOELECTRIC MOTOR, ROBOT HAND, ROBOT, FINGER ASSIST APPARATUS, ELECTRONIC COMPONENT CONVEYING APPARATUS, ELECTRONIC COMPONENT INSPECTING APPARATUS, LIQUID FEED PUMP, PRINTING APPARATUS, ELECTRONIC TIMEPIECE, AND PROJECTING APPARATUS

(71) Applicant: Seiko Epson Corporation, Tokyo (JP)

(72) Inventors: Koichi KAMIJO, Matsumoto (JP); Osamu MIYAZAWA, Shimosuwa (JP)

(21) Appl. No.: 14/561,747

(22) Filed: Dec. 5, 2014

(30) Foreign Application Priority Data
Dec. 6, 2013 (JP) 2013-252753

(51) Int. Cl. B25J 15/02; B25J 17/00; H02N 2/04; H01L 41/09; H01L 41/053

(52) U.S. Cl. CPC B25J 15/0253; H01L 41/0933; H01L 41/053; H02N 2/04; B25J 17/00

(57) ABSTRACT

A supporting portion disposed in parallel to a joint portion to which a vibrating body capable of generating a bending vibration is jointed and configured to support the vibrating body and the joint portion is provided, and the joint portion and the supporting portion are coupled with a plurality of coupling portions. The supporting portion has rigidity higher than that of the joint portion.

### BACKGROUND

1. Technical Field

The present invention relates to a piezoelectric motor, a robot hand, a robot, a finger assist apparatus, an electronic component conveying apparatus, an electronic component inspecting apparatus, a liquid feed pump, a printing apparatus, an electronic timepiece, and a projecting apparatus.

2. Related Art

A piezoelectric motor configured to drive an object by vibrating a vibrating body including a piezoelectric material is known. The piezoelectric motor is characterized by being capable of obtaining a large drive force although being smaller than an electromagnetic motor using an electromagnetic force, and being capable of positioning the object at a high resolution capability.

The piezoelectric motor is operated in the following principle. First of all, a voltage is applied to a vibrating body to cause the vibrating body to generate a predetermined vibration. Then, an end portion of the vibrating body moves along a specific trajectory, and hence an object may be driven frictionally by bringing the end portion into abutment with the object adequately. From the operation principle as described above, if the vibrating body moves by receiving a reaction force from the object, a sufficient drive force cannot be transmitted to the object. Therefore, the vibrating body needs to be supported so as not to move even though a reaction force is applied. Accordingly, JP-A-8-237971 proposes a supporting structure including a plurality of coupling portions extending from a side surface in a bending direction of the vibrating body performing a bending vibration and configured to couple the vibrating body with a fixing portion, and the plurality of coupling portions extending in the same direction with respect to the vibrating body are connected by a supporting portion.

However, with the vibrating body supporting structure as described in JP-A-8-237971, there is a problem that driving characteristics of the piezoelectric motor are affected from the following reasons. First of all, there is a case where a resonance may occur unintentionally in the supporting portion by the vibration of the vibrating body transmitted to the supporting portion via the coupling portions. The resonance disturbs the original vibration of the vibrating body, and hence the trajectory of the movement of the end portion is disordered. Accordingly, modes of abutment such as a strength of abutment of the end portion of the vibrating body with the object and a range (stroke) of abutment of the end portion with the object on the trajectory of movement vary. Consequently, a predetermined drive force cannot be transmitted to the object, and hence the driving characteristics of the piezoelectric motor such as an efficiency of driving of the object and positioning accuracy of the object may be lowered.

### SUMMARY

An advantage of some aspects of the invention is to provide a technology which is capable of supporting a vibrating body without affecting driving characteristics of a piezoelectric motor.

A piezoelectric motor according to an aspect of the invention employs the following configuration. That is, an aspect of the invention is directed to a piezoelectric motor including: a vibrating body capable of generating a bending vibration; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

The term “rigidity” used in the aspect of the invention means a “nature that resists deformation caused by an external force when the external force is applied”. Examples of the term “the rigidity of the supporting portion is high” include that the amount of deflection when the supporting portion is pressed is small, that the amount of bending when the supporting portion is bent is small, and the amount of twisting when the supporting portion is twisted is small.

In this configuration, even though a vibration (vibration allowed at the joint portion) generated by the vibrating body is transmitted to the supporting portion, the vibration is suppressed (is not allowed) at the supporting portion having rigidity higher than that of the joint portion. By restraining the unintentional occurrence of the resonance in the supporting portion in this manner, the original vibration of the vibrating body is not disturbed, and the end portion of the vibrating body moves along a specific trajectory, so that a predetermined drive force may be transmitted to the object. Consequently, the vibrating body can be supported while maintaining driving characteristics of the piezoelectric motor.

The piezoelectric motor according to the aspect of the invention described above may be provided with a reinforcing member configured to enhance the rigidity of the supporting portion.

In this configuration, since the rigidity of the supporting portion becomes higher than the rigidity of the joint portion and hence vibration is restrained, so that unintentional occurrence of the resonance in the supporting portion may be restrained.

In the piezoelectric motor provided with the reinforcing member according to the aspect of the invention described above, the reinforcing member may contain a vibration damping material.

In this configuration, since the vibration damping material disperses vibration energy absorbed thereby as heat and sound to damp the vibration transmitted to the supporting portion, unintentional occurrence of the resonance in the supporting portion may be restrained more reliably.

In the piezoelectric motor according to the aspect of the invention described above, the supporting portion may include a bent portion bent along a segment intersecting a direction of bending of the vibrating body.

In this configuration, in a portion of the supporting portion provided with the bent portion, the rigidity of the supporting portion becomes higher than that of the joint portion and hence the vibration is restrained, so that unintentional occurrence of the resonance in the supporting portion may be restrained.

In the piezoelectric motor according to the aspect of the invention described above, the supporting portion may be formed to have a thickness larger than that of the joint portion.

In this configuration, the rigidity of the supporting portion becomes higher than the rigidity of the joint portion and hence vibration is restrained, so that unintentional occurrence of the resonance in the supporting portion may be restrained.

In the piezoelectric motor according to the aspect of the invention described above, the supporting portion may be formed of a material having rigidity higher than that of the joint portion.

In this configuration, the rigidity of the supporting portion becomes higher than the rigidity of the joint portion and hence vibration is restrained, so that unintentional occurrence of the resonance in the supporting portion may be restrained.

In the piezoelectric motor according to the aspect of the invention as described above, the joint portion, the supporting portion, and the coupling portions may be formed integrally from a single plate member.

In this configuration, a process of joining these members (fastening by a joint screw, adhesion with an adhesive agent, point welding, and so on) may be omitted, so that manufacture of the piezoelectric motor may be facilitated in comparison with the case where these members are provided separately. In addition, since the member such as the joint screw is no longer necessary, reduction of manufacturing cost of the piezoelectric motor is achieved.

In the piezoelectric motor including the joint portion, the supporting portion, and the coupling portions formed integrally according to the aspect of the invention described above, a leaf spring configured to bias the vibrating body toward the object to be driven by the piezoelectric motor may be formed by bending a single plate member to form the joint portion, the supporting portion, and the coupling portions integrally.

In this manner, by forming the leaf spring integrally with the joint portion, the supporting portion, and the coupling portions, facilitating the manufacture of the piezoelectric motor by omitting a process of joining the leaf spring or reducing the manufacturing cost without necessity of the member such as a joint screw is achieved.

In the piezoelectric motor including the joint portion, the supporting portion, the coupling portions, and the leaf spring formed integrally according to the aspect of the invention described above, a fixing portion configured to fix the piezoelectric motor at a predetermined position may be formed integrally with the joint portion, the supporting portion, the coupling portions, and the leaf spring by bending a single plate member integrally.

In this manner, by forming the fixing portion integrally with the joint portion, the supporting portion, the coupling portions, and the leaf spring, facilitating the manufacture of the piezoelectric motor by omitting a process of joining the fixing portion or reducing the manufacturing cost without necessity of the member such as the joint screw is achieved.

In the piezoelectric motor according to the aspect of the invention as described above, a front node portion closer to the object, a rear node portion farther from the object, and a middle node portion between the front node portion and the rear node portion are provided on the vibrating body as node portions having an amplitude of the bending vibration smaller than that of an end portion on a side abutting against the object that the piezoelectric motor drives, and the coupling portions may be provided at selected two or more of the front node portion, the middle node portion, and the rear node portion.

With the provision of the coupling portions on the node portions of the vibrating body in this manner, vibrations to be transmitted to the supporting portion via the coupling portions may be reduced to restrain the unintentional occurrence of resonance in the supporting portion in comparison with the case where the coupling members are provided at portions different from the node portions (antinode portions having an amplitude of the bending vibration equivalent to the end portion on the side of abutting against the object). Since the transmission (release) of the vibration to an outer portion (the coupling portions or the supporting portion) of the vibrating body may be restrained, the object may be driven efficiently by reducing a loss of driving energy.

The aspect of the invention may be construed as the following configuration. That is, another aspect of the invention can be construed as a robot hand configured to be capable of grasping an object with a finger portion, including: a base member having the finger portion extending upright so as to be movable; a movable portion interlocked with a movement of the finger portion or a rotation of joints of the finger portion with respect to the base member; a vibrating body capable of generating a bending vibration; an abutting portion configured to abut against the movable portion and drive the movable portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the robot hand according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the movable portion, and accuracy of gripping the object with the finger portion can be enhanced.

The aspect of the invention may be construed as the following configuration. That is, another aspect of the invention can be construed as a robot including: an arm portion provided with a rotatable joint portion; a hand portion provided on the arm portion; a body portion provided with the arm portion; a movable portion interlocked with a rotation of the joint portion; a vibrating body capable of generating a bending vibration; an abutting portion configured to abut against the movable portion and drive the movable portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the robot according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the movable portion, and accuracy of the movement of the robot can be enhanced. The hand portion may be a hand portion configured to perform, for example, an operation for gripping the object, a screw-tightening operation for tightening a screw, a coating operation, and a welding operation.

The aspect of the invention may be construed as the following configuration. That is, another aspect of the invention can be construed as a finger assist apparatus worn on a finger and configured to assist a bending or stretching movement of the finger, including: a first member to be worn on the finger; a second member worn on the finger and coupled to the first member so as to be rotatable in a direction in which the finger is bent; a movable portion interlocked with the rotation of the second member; a vibrating body capable of generating a bending vibration; an abutting portion configured to abut against the movable portion and drive the movable portion by transmitting the vibration of the vibrating body; a joint portion to which the vibrating body is joined, a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the finger assist apparatus according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the movable portion, and accuracy of assisting the movement of the finger bending or stretching can be enhanced.

The aspect of the invention may be construed as the following configuration. That is, another aspect of the invention can be construed as an electronic component conveying apparatus provided with a gripping portion configured to grip an electronic component, including: a movable portion interlocked with the movement of the gripping portion that grips the electronic component; a vibrating body capable of generating a bending vibration; an abutting portion configured to abut against the movable portion and drive the movable portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the electronic component conveying apparatus according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the movable portion, and accuracy of conveying the electronic component can be enhanced.

The aspect of the invention may be construed as the following configuration. That is, another aspect of the invention construed as an electronic component inspection apparatus including: a gripping portion configured to grip an electronic component; an inspecting portion configured to inspect the electronic component; a movable portion interlocked with the movement of the gripping portion that grips the electronic component; a vibrating body capable of generating a bending vibration; an abutting portion configured to abut against the movable portion and drive the movable portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the electronic component inspection apparatus according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the movable portion, and accuracy of inspecting the electronic component can be enhanced.

The aspect of the invention may be construed as the following configuration. That is, another aspect of the invention can be configured as a liquid feed pump including: a tube which allows liquid to flow therethrough; a closing portion configured to abut against the tube and close the tube; a moving portion configured to move the closing portion; a vibrating body capable of generating a bending vibration; an abutting portion configured to abut against the moving portion and drive the moving portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the liquid feed pump according to the aspect of the invention configured in this manner, since the support of the vibrating body may be enhanced to prevent the vibrating body from being moved by a reaction force that the abutting portion receives from the moving portion without affecting the vibration of the vibrating body, the vibration of the vibrating body is adequately transmitted to the moving portion, and accuracy of feeding liquid in the tube can be enhanced.

The aspect of the invention may be construed as the following configuration. That is, another aspect of the invention can be construed as a printing apparatus including: a printhead configured to print an image on a medium; a moving portion configured to move the printhead; a vibrating body capable of generating a bending vibration; an abutting portion configured to abut against the moving portion and drive the moving portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the printing apparatus according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the moving portion, and accuracy of printing an image can be enhanced.

The aspect of the invention may be construed as the following configuration. That is, another aspect of the invention can be construed as an electronic timepiece including: a rotatable rotary disc coaxially provided with a gear; a gear train including a plurality of teeth; a hand connected to the gear train and configured to point out time of the day; a vibrating body capable of generating a bending vibration; an abutting portion configured to abut against the rotary disc and drive the rotary disc by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the electronic timepiece according to the aspect of the invention configured in this manner, since the support of the vibrating body may be enhanced to prevent the vibrating body from being moved by a reaction force that the abutting portion receives from the rotary disc without affecting the vibration of the vibrating body, the vibration of the vibrating body is adequately transmitted to the rotary disc, and accuracy of the movement of the electronic timepiece can be enhanced.

The aspect of the invention may be construed as the following configuration. That is, another aspect of the invention can be construed as a projecting apparatus including: a light source configured to generate light; a projecting portion including an optical lens and configured to project the light; a moving portion configured to move the optical lens; a vibrating body capable of generating a bending vibration; an abutting portion configured to abut against the moving portion and drive the moving portion by transmitting the vibration of the vibrating body; a joint portion to which the vibrating body is joined; a supporting portion disposed in parallel to the joint portion and configured to support the vibrating body and the joint portion; and a plurality of coupling portions configured to couple the joint portion and the supporting portion, wherein the supporting portion has rigidity higher than that of the joint portion.

With the projecting apparatus according to the aspect of the invention configured in this manner, since the support of the vibrating body may be enhanced to prevent the vibrating body from being moved by a reaction force that the abutting portion receives from the movable portion without affecting the vibration of the vibrating body, the vibration of the vibrating body is adequately transmitted to the moving portion, and accuracy of adjusting the projecting state of light by the optical lens can be enhanced.

### BRIEF DESCRIPTION OF DRAWINGS

The invention will be described with reference to the accompanying drawings, wherein like numbers reference like elements.

FIG. 1 is a perspective view illustrating a structure of a piezoelectric motor of an example.

FIGS. 2A and 2B are explanatory drawings illustrating a structure of a vibrating body.

FIGS. 3A to 3C are explanatory drawings illustrating an operation principle of the piezoelectric motor.

FIG. 4 is an explanatory drawing illustrating a node portion of the vibrating body.

FIG. 5 is an explanatory drawing illustrating a state in which an object is driven by using the piezoelectric motor.

FIG. 6 is an explanatory drawing illustrating a reason why driving characteristics of the piezoelectric motor is changed by a connection of a front coupling portion and a rear coupling portion with a supporting portion.

FIGS. 7A and 7B are explanatory drawings illustrating a structure of a piezoelectric motor of a first modification.

FIGS. 8A to 8D are explanatory drawings illustrating a structure of a piezoelectric motor of a second modification.

FIG. 9 is a perspective view illustrating a structure of a piezoelectric motor of a third modification.

FIG. 10 is an explanatory drawing illustrating the piezoelectric motor of a fourth modification in which coupling portions are provided at a front node portion and a middle node portion of the vibrating body.

FIG. 11 is an explanatory drawing illustrating the piezoelectric motor of a fifth modification in which the coupling portions are at all of the node portions at three positions.

FIG. 12 is an explanatory drawing illustrating a piezoelectric motor of a sixth modification in which the coupling portions are formed to be asymmetry on both sides of the vibrating body in a Y-direction.

FIGS. 13A and 13B are explanatory drawings exemplifying a robot hand having the piezoelectric motor of the example or the modification integrated therein.

FIG. 14 is an explanatory drawing illustrating a single arm robot provided with the robot hand.

FIG. 15 is an explanatory drawing illustrating a plural arm robot provided with the robot hand.

FIGS. 16A and 16B are explanatory drawings exemplifying a finger assist apparatus having the piezoelectric motor of the example or the modification integrated therein.

FIG. 17 is a perspective view exemplifying an electronic component inspecting apparatus including the piezoelectric motor of the example or the modification integrated therein.

FIG. 18 is an explanatory drawing about a fine-adjustment mechanism integrated in a gripping device.

FIGS. 19A and 19B are explanatory drawings exemplifying a liquid feed pump including the piezoelectric motor of the example or the modification integrated therein.

FIG. 20 is a perspective drawing exemplifying a printing apparatus having the piezoelectric motor of the example or the modification integrated therein.

FIG. 21 is an explanatory drawing exemplifying an internal structure of an electronic timepiece having the piezoelectric motor of the example or the modification integrated therein.

FIG. 22 is an explanatory drawing exemplifying a projection apparatus having the piezoelectric motor of the example or the modification integrated therein.

### DESCRIPTION OF EXEMPLARY EMBODIMENTS

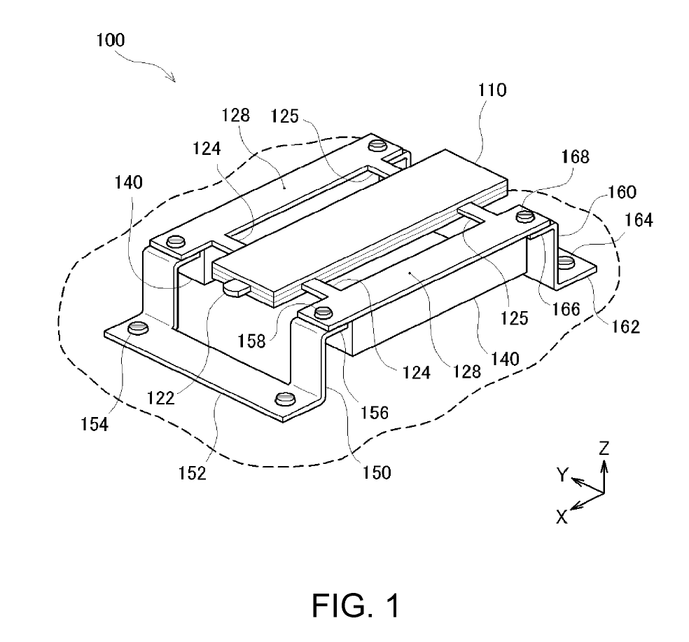

FIG. 1 is a perspective view illustrating a structure of a piezoelectric motor 100 of an example. As illustrated in the drawing, the piezoelectric motor 100 of the example roughly includes a vibrating body 110 including a piezoelectric material, supporting portions 128 configured to support the vibrating body 110, and two leaf springs (front leaf spring 150 and rear leaf spring 160) configured to bias the vibrating body 110 in a predetermined direction.

The vibrating body 110 has a parallelepiped shape, and is provided with a projecting portion 122 configured to abut against an object to be driven by the piezoelectric motor 100 on an end surface in the longitudinal direction. A detailed structure of the vibrating body 110 will be described with reference to other drawings. The longitudinal direction of the vibrating body 110 is referred below to as an X-direction. In the drawing, the short direction of the vibrating body 110 orthogonal to the X-direction is referred to as a Y-direction, and a thickness direction of the vibrating body 110 orthogonal to the X-direction and the Y-direction is referred to as a Z-direction.

The supporting portions 128 are provided on both sides in parallel in the short direction (Y-direction) of the vibrating body 110, and are coupled by the vibrating body 110 and a plurality of coupling portions (a pair of front coupling portions 124 and a pair of rear coupling portions 125). The front coupling portions 124 and the rear coupling portion 125 are provided apart from each other in the longitudinal direction (X-direction) of the vibrating body 110. The front coupling portions 124 couple a side of the vibrating body 110 provided with the projecting portion 122, and the rear coupling portions 125 couple a side opposite to the side of the vibrating body 110 provided with the projecting portion 122. The supporting portion 128 of this example is a rectangular flat plate formed integrally with the front coupling portions 124 and the rear coupling portions 125 as illustrated in the drawing. Then, a parallelepiped shaped reinforcing member 140 for reinforcing the supporting portions 128 (for enhancing the rigidity) is provided so as to be in tight contact with a lower surface of the supporting portions 128.

The two leaf springs (the front leaf spring 150 and the rear leaf spring 160) are arranged so as to be apart from each other in the longitudinal direction (X-direction) of the vibrating body 110. A pair of the front leaf springs 150 provided on the side of the vibrating body 110 where the projecting portion is provided are formed by bending from a fixing portion 152, which is to be fixed at a position where the piezoelectric motor 100 is installed (an X-Y plane) and with fixing screws 154, in the Z-direction (upward direction in the drawing) so as to interpose the vibrating body 110 therebetween. The front leaf spring 150 faces the X-direction, and may be deflected in the X-direction. A distal end side (the side opposite to the fixing portion 152) of the front leaf spring 150 is bent in the X-direction (inner side in the drawing) to form a base portion 156. End portions of the supporting portions 128 on the front coupling portions 124 side are joined to the base portion 156 by joint screws 158. A method of joining the supporting portions 128 and the base portion 156 may be adhesion or welding.

The rear leaf spring 160 provided on the side opposite to the side where the projecting portion 122 of the vibrating body 110 is provided is formed in plane symmetry with the front leaf spring 150 with respect to a Y-Z plane. In other words, a pair of the rear leaf springs 160 are provided so as to interpose the vibrating body 110 therebetween by being bent from a fixing portion 162, which is fixed with a fixing screw 164, in the Z-direction (upward direction in the drawing) and may be deflected in the X-direction. A distal end side (the side opposite to the fixing portion 162) of the rear leaf spring 160 is bent in the X-direction (toward the near side in the drawing) to form a base portion 166, and end portions of the supporting portions 128 on the rear coupling portions 125 side are joined to the base portion 166 with joint screws 168.

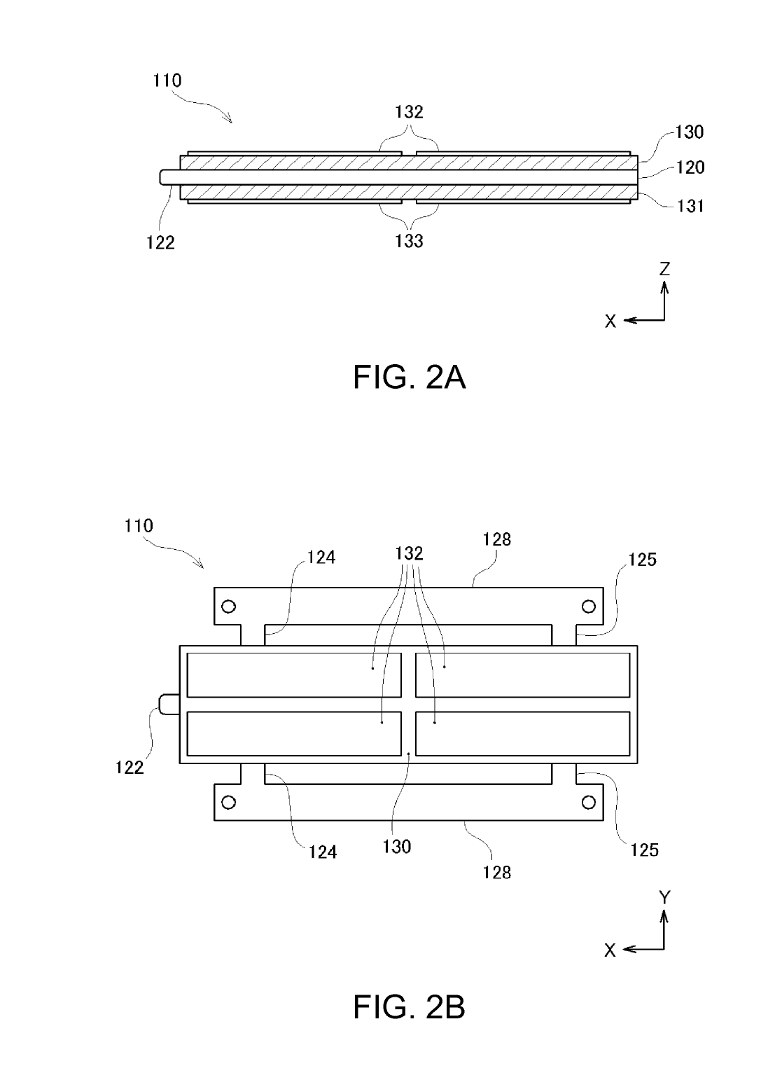

FIGS. 2A and 2B are explanatory drawings illustrating a structure of the vibrating body 110. FIG. 2A illustrates a cross section of the vibrating body 110 taken along an X-Z plane. As illustrated in the drawing, the vibrating body 110 has a laminated structure formed by joining a shim plate 120 formed of a metallic flat plate interposed between two piezoelectric elements (front piezoelectric element 130 and back piezoelectric element 131) including a piezoelectric material and formed into a plate shape. In this example, the shim plate 120 and the piezoelectric elements (front piezoelectric element 130 and back piezoelectric elements 131) are adhered by using a conductive adhesive agent. However, the joining method is not limited thereto, and a direct joining with rivet or the like is also applicable. The piezoelectric elements (front piezoelectric element 130 and back piezoelectric element 131) are provided with electrodes (front electrodes 132 and back electrodes 133) for applying a voltage to the piezoelectric elements on surfaces opposite to surfaces that come into contact with the shim plate 120.

The metallic shim plate 120 has a function not only to reinforce the piezoelectric elements (front piezoelectric element 130 and back piezoelectric element 131), but also as a common electrode for applying a voltage to the front piezoelectric element 130 and the back piezoelectric element 131 and grounded. As described above, the projecting portion 122 configured to abut against the object is provided at the end portion of the vibrating body 110 in the longitudinal direction (X-direction), and the projecting portion 122 is formed integrally with the shim plate 120 by punching a single plate member. The shim plate 120 of this example corresponds to the “joint portion” according to the invention.

FIG. 2B illustrates a plan view of the vibrating body 110 viewed in the Z-direction (front piezoelectric element 130 side). As described above, the front electrodes 132 for applying a voltage to the front piezoelectric element 130 are provided on a surface (upper surface) of the front piezoelectric element 130 opposite to the surface coming into contact with the shim plate 120 and, as illustrated in FIG. 2B, four of the rectangular front electrodes 132 are provided so as to divide the upper surface of the front piezoelectric element 130 into four parts in a reticular pattern. Although illustration is omitted, four of the rectangular back electrodes 133 are similarly provided on a surface (lower surface) of the back piezoelectric element 131 opposite to the surface coming into contact with the shim plate 120 so as to divide the lower surface thereof into four parts in a reticular pattern.

As described above, the supporting portions 128 are provided on the both sides in parallel in the Y-direction of the vibrating body 110, and the vibrating body 110 and the supporting portions 128 are coupled by a pair the of front coupling portions 124 and a pair of the rear coupling portions 125. In the piezoelectric motor 100 of this example, a pair of the front coupling portions 124 and the rear coupling portions 125 and a set of the supporting portions 128 and the shim plate 120 are formed integrally by punching a single metallic flat plate. In this configuration, a process of joining these members (fastening by a joint screw, adhesion with an adhesive agent, point welding, and so on) may be omitted, so that manufacture of the piezoelectric motor 100 may become facilitated in comparison with the case where these members are formed separately. In addition, since the member such as the joint screw is no longer necessary, reduction of manufacturing cost of the piezoelectric motor 100 is achieved.

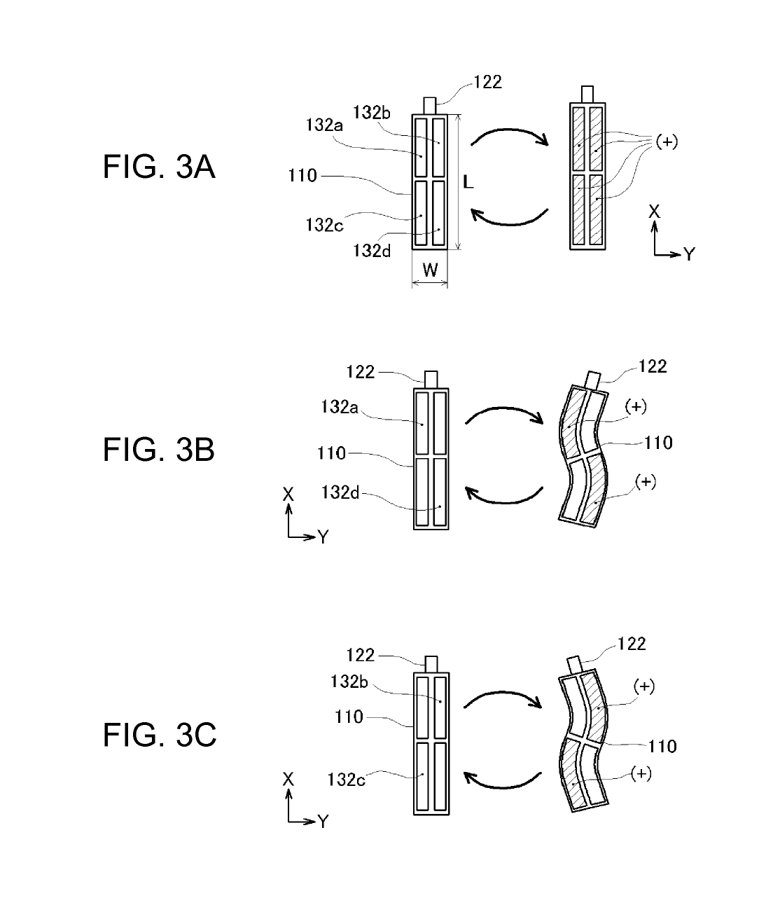

FIGS. 3A to 3C are explanatory drawings illustrating an operation principle of the piezoelectric motor 100. The piezoelectric motor 100 operates by an oval movement of the projecting portion 122 of the vibrating body 110 when a voltage is applied to the front electrodes 132 and the back electrodes 133 of the vibrating body 110 at a regular cycle. The reasons why the projecting portion 122 of the vibrating body 110 makes the oval movement are as follows. The front electrodes 132 provided on the front piezoelectric element 130 and the back electrodes 133 provided on the back piezoelectric element 131 are in plane symmetry with respect to the X-Y plane and basically the same. Therefore, the front electrodes 132 will be described as an example.

First of all, as publicly known, the piezoelectric elements (front piezoelectric element 130 and back piezoelectric elements 131) including the piezoelectric material has a nature of expanding when a positive voltage is applied. Therefore, as illustrated in FIG. 3A, if a procedure of applying the positive voltage to all of the four front electrodes 132 and then releasing the applied voltage is repeated at a specific frequency, the vibrating body 110 (front piezoelectric element 130) may cause a sort of resonant phenomenon, that is, expansion and contraction in the longitudinal direction (X-direction). The operation that the vibrating body 110 repeats expansion and contraction in the longitudinal direction (X-direction) is referred to as “expansion and contraction vibration”, and the direction in which the vibrating body 110 expands and contracts (±X-direction in the drawing) is referred to as “direction of expansion and contraction”.

As illustrated in FIG. 3B or FIG. 3C, when two of the front electrodes 132 at a position of a diagonal line are paired (a pair of a front electrode 132a and a front electrode 132d, or a pair of a front electrode 132b and a front electrode 132c) and a positive voltage at a specific frequency is applied thereto, the vibrating body 110 (the front piezoelectric element 130) is capable of generating a sort of resonant phenomenon in which distal end portions (the portion where the projecting portion 122 is formed) in the longitudinal direction (X-direction) swings in the lateral direction (Y-direction) in the drawing may be generated. For example, as illustrated in FIG. 3B, when a positive voltage having a specific frequency is applied to the pair of the front electrode 132a and the front electrode 132d, the vibrating body 110 repeats the operation to cause the distal end portions in the longitudinal direction to move rightward. As illustrated in FIG. 3C, when a positive voltage having a specific frequency is applied to the pair of the front electrode 132b and the front electrode 132c, the vibrating body 110 repeats the operation to cause the distal end portions in the longitudinal direction to move leftward. Such an operation of the vibrating body 110 is referred to as “bending vibration”, and the direction in which the vibrating body 110 performs the bending vibration (±Y-direction in the drawing) is referred to as “bending direction”.

By selecting a physical property of the front piezoelectric element 130 and dimensions of the front piezoelectric element 130 (width W, length L, and thickness T) adequately, resonance of the bending vibration may be induced and, simultaneously, resonance of an “expansion and contraction vibration” may also be induced. Consequently, in the case where a voltage is applied to the pair of the front electrode 132a and the front electrode 132d in a mode illustrated in FIG. 3B, the distal end portion of the vibrating body 110 (the portion where the projecting portion 122 is provided) moves along a trajectory of an oval shape (oval movement) clockwise on the drawing. In the case where a voltage is applied to the pair of the front electrode 132b and the front electrodes 132c in a mode illustrated in FIG. 3C, the distal end portion of the vibrating body 110 makes a counterclockwise oval movement on the drawing. Completely the same as the front piezoelectric element 130 applies to the back piezoelectric element 131 as well.

The piezoelectric motor 100 drives the object by using the oval movement of the vibrating body 110 as described above. In other words, the piezoelectric motor causes the oval movement in a state in which the projecting portion 122 of the vibrating body 110 is pressed against the object. Then, the projecting portion 122 repeats an operation of moving from the left to the right (or from the right to the left) in a state in which the vibrating body 110 is pressed against the object when the vibrating body 110 expands, and restoring the original state in a state of being apart from the object when the vibrating body 110 contracts. Consequently, the object is driven in one direction by a frictional force received from the projecting portion 122.

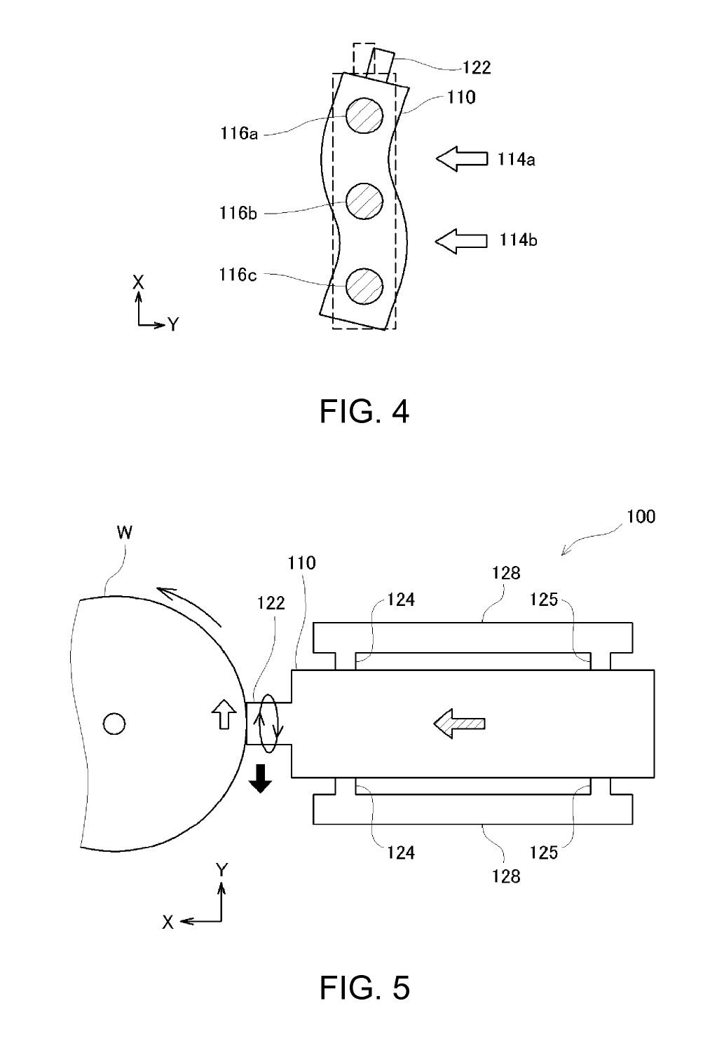

Now, the vibrating body 110 which generates the bending vibration by the application of the voltage as described above does not vibrate uniformly as a whole, but has portions (node portions) having a smaller amplitude of the bending vibration in comparison with the distal end portion where the projecting portion 122 is provided. FIG. 4 is an explanatory drawing illustrating a node portion 116 of the vibrating body 110. FIG. 4 illustrates a state in which no voltage is applied to the vibrating body 110 is indicated by a broken line, and a state in which a voltage is applied to the pair of the front electrode 132a and the front electrode 132d of the vibrating body 110 and hence the distal end portion moves rightward is indicated by a solid line. As illustrated in the drawing, the vibrating body 110 includes antinode portions 114 (114a and 114b) which vibrate at the same amplitude as the end portions in the X-direction at two position, and the node portions 116 (a front node portion 116a, a middle node portion 116b, and a rear node portion 116c) at three positions where the amplitude of the bending vibration is smaller.

On both sides of the front node portion 116a in the Y-direction, which is located on the side closer to the projecting portion 122 from among the node portions 116 at three positions, the pair of front coupling portions 124 described above are provided, and on both sides of the rear node portion 116c located on the side far from the projecting portion 122 in the Y-direction, the pair of rear coupling portions 125 described above are provided (See FIG. 2B). In this manner, by providing the coupling portions 124 and 125 on the both sides of the node portion 116, coupling with the coupling portions 124 and 125 without hindering the bending vibration of the vibrating body 110 is enabled in comparison with the case where the coupling portions 124 and 125 are provided at different portions from the node portions 116 (such as the antinode portions 114), transfer of the vibrations generated in the vibrating body 110 to the leaf springs 150 and 160 via the coupling portion 124 and 125 (release of the vibration) may be restrained. Consequently, the object may be driven efficiently by reducing driving energy loss.

FIG. 5 is an explanatory drawing illustrating the state in which the object is driven by using the piezoelectric motor 100. FIG. 5 illustrates an example in which a rotor W is rotated as an object. The piezoelectric motor 100 is installed in the state in which the projecting portion 122 of the vibrating body 110 is pressed against an outer peripheral surface of the rotor W. As described above, the piezoelectric motor 100 includes two of the leaf springs (the front leaf spring 150 and the rear leaf spring 160), and if the leaf springs 150 and 160 are bent toward a side opposite to the side where the projecting portion 122 of the vibrating body 110 is provided, the vibrating body 110 may be biased (pressed) toward the side where the projecting portion 122 is provided by a restoration force. Then, if the projecting portion 122 makes an oval movement by the vibration of the vibrating body 110, the rotor W may be rotated by a frictional force generated between the projecting portion 122 and the rotor W.

In this manner, the projecting portion 122 providing the rotor W with a drive force receives a reaction force having the same magnitude as, and in a direction opposite to, the drive force from the rotor W. If the vibrating body 110 is moved by the reaction force, a sufficient drive force cannot be transmitted to the rotor W. Therefore, in the piezoelectric motor 100 of this example, the front coupling portions 124 and the rear coupling portions 125 are provided to couple the vibrating body 110 with the supporting portions 128 so that the vibrating body 110 is prevented from being moved by the reaction force.

First of all, by providing the front coupling portions 124 on the front node portion 116a of the vibrating body 110, the side closer to the projecting portion 122, which receives the reaction force, is coupled to the supporting portions 128 to resist the reaction force. However, only with the coupling between the front node portion 116a and the supporting portions 128, the projecting portion 122 moves away from the rotor W while swinging the side of the vibrating body 110 opposite to the projecting portion 122 (rear side) around about the front node portion 116a as a supporting point, so that a drive stroke (a range in which the projecting portion 122 transmits the drive force to the rotor W on an oval trajectory) can hardly be obtained. Therefore, by providing the rear coupling portions 125 on the rear node portion 116c of the vibrating body 110 to couple the side far from the projecting portion 122 with the supporting portions 128, the swinging-around movement of the rear side of the vibrating body 110 may be restrained, so that a significant drive stroke may be secured against the reaction force.

Furthermore, in the piezoelectric motor 100 of this example, the front coupling portions 124 and the rear coupling portions 125 are connected by the supporting portions 128. Accordingly, in comparison with the case where the supporting portions 128 are not provided, the reaction force received by the projecting portion 122 may be transmitted not only to the front leaf spring 150, but also to the rear leaf spring 160 via the supporting portions 128 to resist the reaction force. Therefore, the support of the vibrating body 110 to prevent the vibrating body 110 from moving due to the reaction force can be further enhanced. However, if the front coupling portions 124 and the rear coupling portions 125 are connected by the supporting portions 128, driving characteristics of the piezoelectric motor 100 may change.

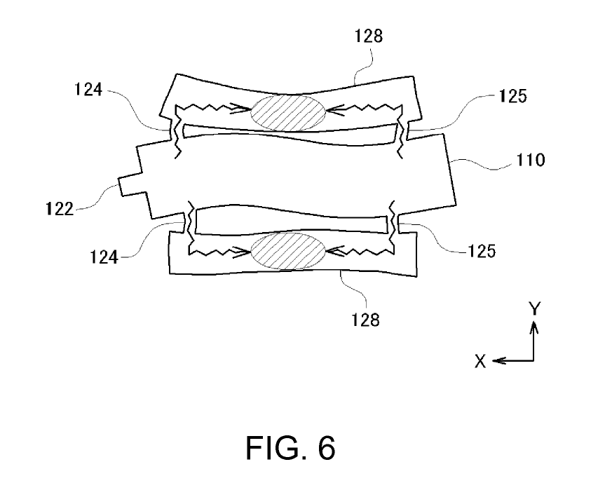

FIG. 6 is an explanatory drawing illustrating a reason why the driving characteristics of the piezoelectric motor 100 are changed by a connection of the front coupling portion 124 and the rear coupling portion 125 with the supporting portions 128. As described above, the front coupling portions 124 and the rear coupling portions 125 are provided at the node portions 116 subjected to a little vibration of the vibrating body 110. However, if the slight vibration in the node portions 116 is transmitted to the supporting portions 128 via the front coupling portions 124 and the rear coupling portions 125, a resonance may occur unintentionally in the supporting portions 128. If the resonance returns back to the vibrating body 110 via the coupling portions 124 and 125 and the original vibration of the vibrating body 110 is disturbed thereby disordering the trajectory of the oval movement of the projecting portion 122, a mode of abutment between the projecting portion 122 and the rotor W is changed. For example, if the diameter of the oval movement is reduced, the strength of abutment of the projecting portion 122 with respect to the rotor W may be reduced, or the range (stroke) that the projecting portion 122 abuts against the rotor Won the oval trajectory may be reduced. Therefore, the drive force cannot be transmitted sufficiently to the rotor W and, consequently, the driving characteristics of the piezoelectric motor 100 such as efficiency for rotating the rotor W or accuracy of positioning of the rotor W at a predetermined rotational angle may be lowered.

Therefore, in the piezoelectric motor 100 of this example, as described with reference to FIG. 1, the reinforcing member 140 is provided in tight contact with the supporting portions 128. Accordingly, even though the rigidity of the supporting portions 128 may be increased with reference to the shim plate 120 to which the piezoelectric elements 130 and 131 are joined, and the vibration generated in the node portions 116 of the vibrating body 110 (vibration allowed by the shim plate 120) is transmitted to the supporting portions 128, the vibration of the supporting portions 128 having a high rigidity is restrained (not allowed). By restraining the unintended occurrence of the resonance in the supporting portion 128 in this manner, the original vibration of the vibrating body 110 is not disturbed, and the projecting portion 122 makes an oval movement along a specific trajectory, so that a predetermined drive force may be transmitted to the rotor W. Consequently, the driving characteristics of the piezoelectric motor 100 may be maintained.

The term “rigidity” of this example means “nature that resists deformation caused by an external force applied”. As a method of evaluating the fact that “the supporting portions 128 have rigidity higher than that of the shim plate 120”, the following method may be exemplified. For example, when the amounts of deflection of the supporting portions 128 and the shim plate 120 are compared by pressing with an application of the same magnitude of force to center portions of them in the X-direction from the Z direction, it is accepted if the amount of deflection of the supporting portions 128 is smaller than that of the shim plate 120. Alternatively, when the amounts of bending of the supporting portions 128 and the shim plate 120 are compared by fixing at one ends of them in the X-direction and the same magnitude of force is applied and bend the other ends from the Z direction, it is accepted if the amount of bending of the supporting portions 128 is smaller than that of the shim plate 120. Alternatively, when the amounts of twisting of the supporting portions 128 and the shim plate 120 are compared by fixing at one ends of them in the X-direction and twisting the other ends with the same magnitude of force about in the X-direction as an axis, it is accepted if the amount of twisting of the supporting portions 128 is smaller than that of the shim plate 120. These comparative evaluations are performed before joining the piezoelectric elements 130 and 131 to the shim plate 120, whereby an evaluation with higher degree of accuracy is achieved.

In the piezoelectric motor 100 of this example, the front coupling portions 124 and the rear coupling portions 125 are provided at the node portions 116 of the vibrating body 110 generating less vibration as described above. Therefore, in comparison with the case where the coupling portions 124 and 125 are provided at portions other than the node portions 116 (such as the antinode portions 114), unintentional occurrence of the resonance in the supporting portion 128 in this manner may be restrained by reducing the vibration transmitted to the supporting portions 128 via the coupling portions 124 and 125.

The material to be used for the reinforcing member 140 may include a material having not only a high rigidity, but also a small coefficient of vibration (so-called a vibration damping material). In this configuration, by using the vibration damping material for the reinforcing member 140, the vibration damping material disperses vibration energy absorbed thereby as heat and sound to damp the vibration transmitted to the supporting portion 128, and hence unintended occurrence of the resonance in the supporting portion 128 may be restrained further reliably.

Modifications of the piezoelectric motor 100 of this example described above will be described below. In the description of the modifications, components which are the same as those of the example described above are denoted by the same reference signs as the example, whereby the detailed description will be omitted.

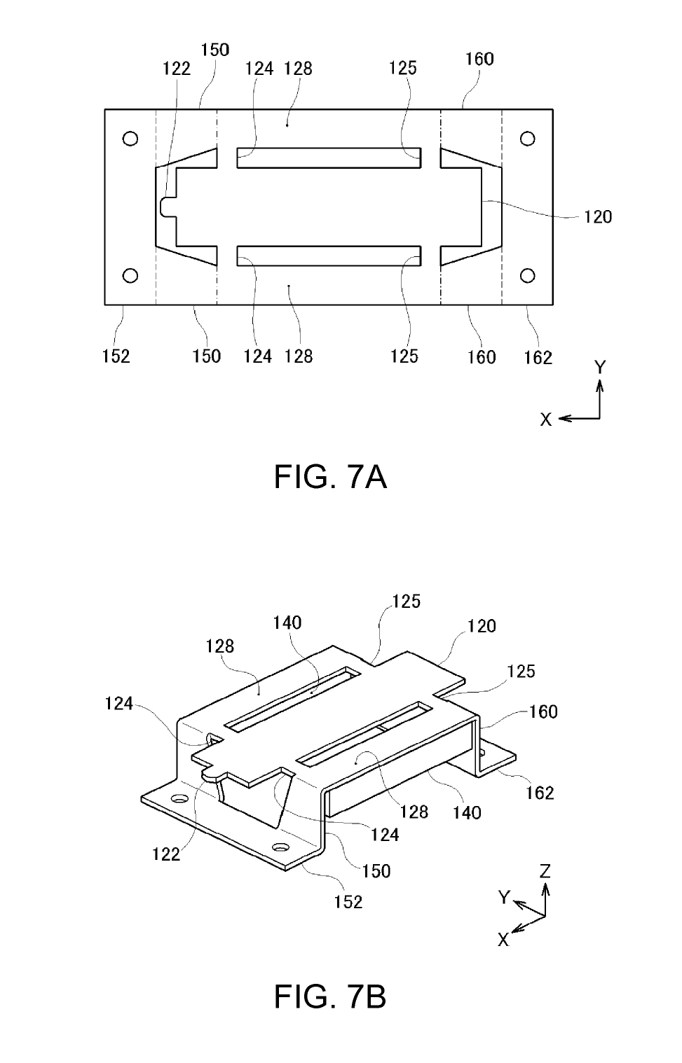

FIGS. 7A and 7B are explanatory drawings illustrating the structure of the piezoelectric motor 100 of a first modification. In the example described above, the shim plate 120, the coupling portions 124 and 125, and the supporting portions 128 are formed integrally, and separately, the front leaf spring 150 and the rear leaf spring 160 are provided. In contrast, in the piezoelectric motor 100 of the first modification, the shim plate 120, the coupling portions 124 and 125, the supporting portions 128, the leaf springs 150 and 160, and the fixing portions 152 and 162 are integrally formed by punching and bending a single metallic flat plate.

FIG. 7A illustrates a deployment view of a single metallic flat plate after having punched and before being bent. As illustrated in the drawing, the front leaf spring 150 is connected to end portions of the supporting portions 128 on the side of the front coupling portions 124 and the rear leaf spring 160 is connected to end portions of the supporting portions 128 on the side of the rear coupling portions 125. The fixing portions 152 and 162 are connected to the side opposite to the side connected to the supporting portions 128 of the leaf springs 150 and 160.

FIG. 7B is a perspective view of the single metallic plate in FIG. 7A illustrating the state after valley bending along broken lines and mountain bending along dashed lines. After having bent as described above, the front piezoelectric element 130 and the back piezoelectric element 131 are joined to the shim plate 120, and the reinforcing member 140 is mounted on the supporting portions 128 in a tight contact manner, whereby the piezoelectric motor 100 of the first modification is manufactured. In FIG. 7B, illustration of the front piezoelectric element 130 and the back piezoelectric element 131 is omitted.

In this manner, by forming the shim plate 120, the coupling portions 124 and 125, the supporting portions 128, the leaf springs 150 and 160, and the fixing portions 152 and 162 integrally by punching and bending a single metallic flat plate, a process of joining these members with each other is omitted in comparison with the case where these members are formed separately, so that the manufacture of the piezoelectric motor 100 is facilitated. In addition, since the member such as the joint screw is no longer necessary, reduction of manufacturing cost of the piezoelectric motor 100 is achieved.

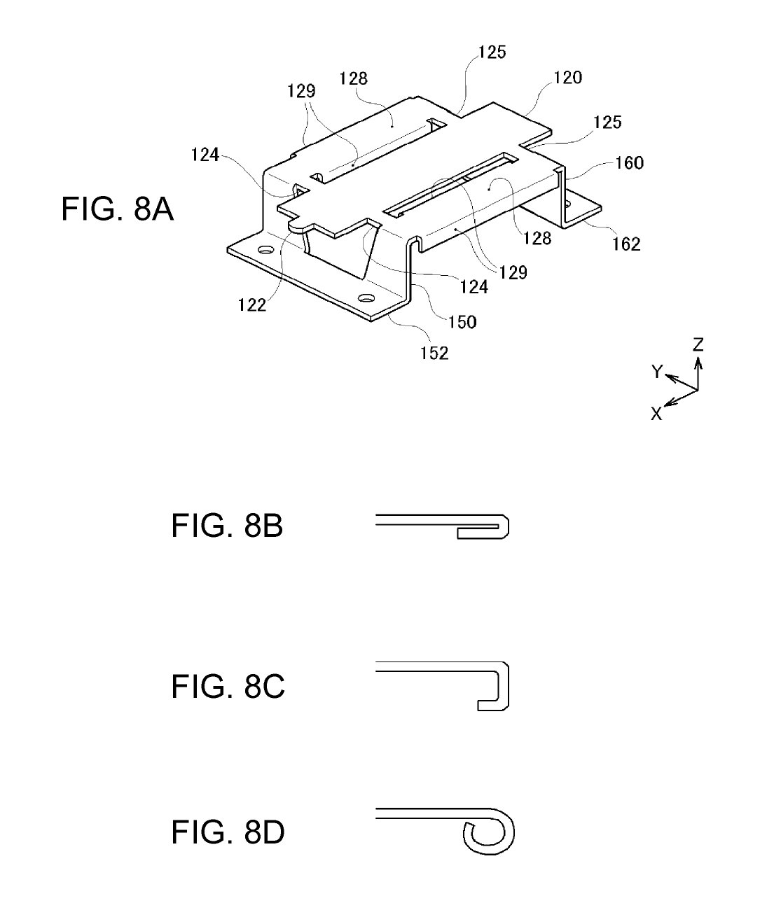

FIGS. 8A to 8D are explanatory drawings illustrating a structure of the piezoelectric motor 100 of a second modification. FIG. 8A is a perspective view illustrating the piezoelectric motor 100 of the second modification. In FIG. 8A, illustration of the front piezoelectric element 130 and the back piezoelectric element 131 is omitted. As illustrated in the drawing, in the piezoelectric motor 100 of the second modification, unlike the example and the first modification described above, the reinforcing member 140 is not provided in a tight contact manner with the supporting portions 128 and, instead, bent portions 129 bent at a right angle with respect to the supporting portions 128 are provided on both sides of the supporting portions 128 in the Y-direction.

In this manner, by bending both sides of the supporting portions 128 in the Y-direction, rigidity higher than that of the shim plate 120 is ensured at the portions of the supporting portions 128 provided with the bent portions 129. Accordingly, in the same manner as the example described above, even though the vibration generated in the vibrating body 110 (shim plate 120) is transmitted to the supporting portions 128, the vibration may be restrained in the supporting portions 128. Therefore, unintended occurrence of resonance in the supporting portions 128 is retrained, so that the driving characteristics of the piezoelectric motor 100 may be maintained. The bent portion 129 may be formed integrally with the shim plate 120, the coupling portions 124 and 125, and the supporting portions 128 from a single metallic flat plate, the rigidity of the supporting portions 128 may be enhanced without preparing an additional member (reinforcing member 140).

The bending work to be performed on the supporting portions 128 is not limited to a mode of bending at a right angle with respect to the supporting portions 128 as illustrated in FIG. 8A. For example, as illustrated in FIG. 8B, a mode of bending by 180° with respect to the supporting portions 128 is also applicable. As illustrated in FIG. 8C, bending to form an angular C-shaped cross section is also applicable. Alternatively, as illustrated in FIG. 8D, curving so as to form a circular shape in cross section is also applicable. The bending work may be applied only for one of the both sides of the supporting portions 128 in the Y-direction instead of the both sides.

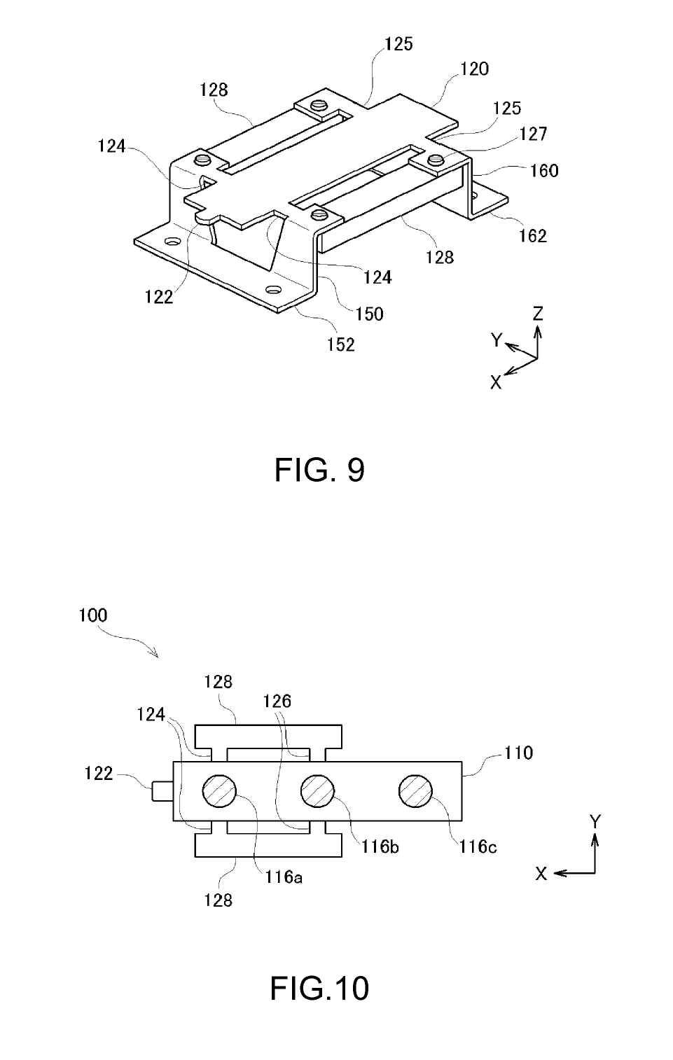

FIG. 9 is a perspective view illustrating a structure of the piezoelectric motor 100 of a third modification. In the example and the first example described above, the supporting portions 128 are formed integrally with the shim plate 120 and the coupling portions 124 and 125, and the reinforcing member 140 is mounted in tight contact with the supporting portions 128 to achieve rigidity higher than that of the shim plate 120. In contrast, in the piezoelectric motor 100 of the third modification, the supporting portions 128 are provided separately from the shim plate 120 and the coupling portions 124 and 125 as illustrated in FIG. 9, and the supporting portions 128 itself are formed to be thicker than the shim plate 120. The supporting portions 128 of the third modification are assumed to be formed of the same material as that of the shim plate 120. In the illustrated example, the coupling portions 124 and 125 and the supporting portions 128 are joined with the joint screws 127. However, the joining method may be adhesion or welding. In FIG. 9, illustration of the front piezoelectric element 130 and the back piezoelectric element 131 is omitted.

In this manner, by forming the supporting portions 128 to be thicker than the shim plate 120, the rigidity of the supporting portions 128 may be set to be higher than that of the shim plate 120. Accordingly, in the same manner as the example described above, the vibration transmitted from the vibrating body 110 (shim plate 120) may be restrained in the supporting portions 128. Therefore, unintended occurrence of resonance in the supporting portions 128 is retrained, so that the driving characteristics of the piezoelectric motor 100 may be maintained.

In the third modification described above, the rigidity is enhanced by forming the supporting portions 128 to be thicker than the shim plate 120. However, the supporting portions 128 may be formed of a material having rigidity higher than that of the shim plate 120. The material used for the supporting portions 128 may include the vibration damping material in addition to a high rigidity. By using the vibration damping material, the vibration transmitted to the supporting portions 128 is damped, and hence unintended occurrence of resonance may be restrained further reliably.

In the above-described embodiment, the coupling portions 124 and 125 are provided at the front node portion 116a and the rear node portion 116c from among the three node portions 116 of the vibrating body 110 where the amplitude of the bending vibration is small. However, the positions where the coupling portions are to be provided are not limited thereto, and two or more positions may be selected from among the three node portions 116.

FIG. 10 is an explanatory drawing illustrating the piezoelectric motor 100 of a fourth modification in which the coupling portions are provided at the front node portion 116a and the middle node portion 116b of the vibrating body 110. As illustrated in the drawing, the front coupling portions 124 extend from the both sides of the front node portion 116a of the vibrating body 110 in the Y-direction, and central coupling portions 126 extend from the both sides of the middle node portion 116b in the Y-direction. The coupling portions 124 and 126 are coupled to the vibrating body 110 and the supporting portions 128. In the piezoelectric motor 100 of the fourth modification, the length of the supporting portions 128 for connecting the coupling portions is reduced in comparison with the case where the front coupling portions 124 and 125 are provided at the front node portion 116a and the rear node portion 116c of the vibrating body 110, and hence vibration areas of the supporting portions 128 are reduced, so that the unintended occurrence of resonance may be restrained.

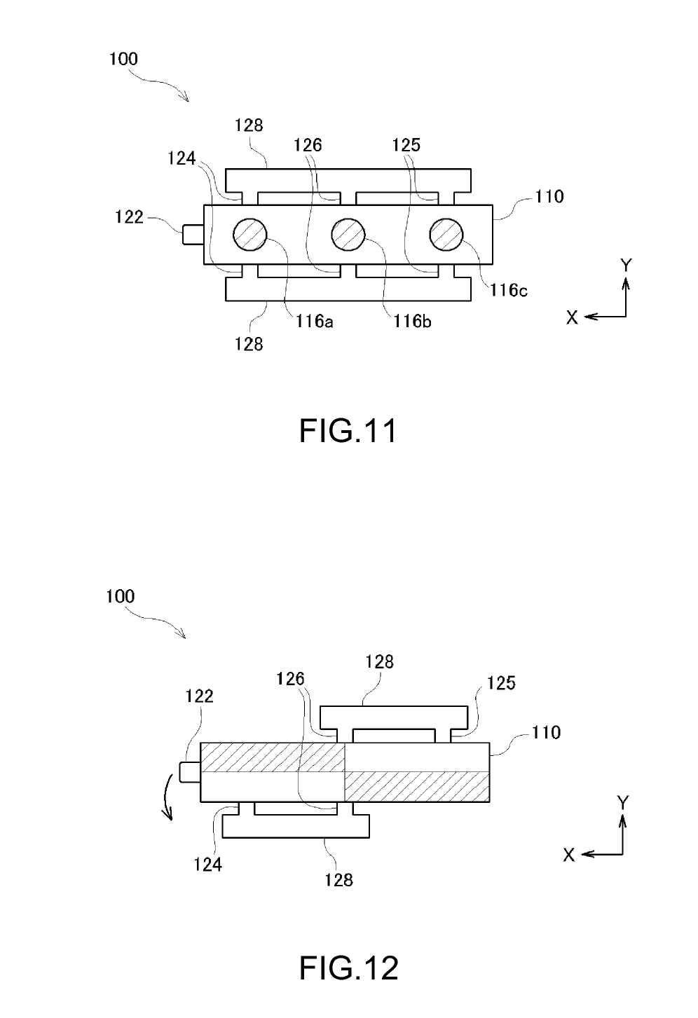

FIG. 11 is an explanatory drawing illustrating the piezoelectric motor 100 of a fifth modification in which the coupling portions are provided at all of the node portions 116 at three positions. As illustrated in the drawing, the front coupling portions 124 extend from the both sides of the front node portion 116a of the vibrating body 110 in the Y-direction, the central coupling portions 126 extend from the both sides of the middle node portion 116b in the Y-direction, and the rear coupling portions 125 extend from the both sides of the rear node portion 116c in the Y-direction. The coupling portions 124, 125 and 126 are coupled to the vibrating body 110 and the supporting portions 128. In the piezoelectric motor 100 of the fifth modification, the vibrating body 110 is supported further firmly in comparison with the case where the coupling portions are provided at two positions from among the three node portions 116. Therefore, even though a large drive force is transmitted to the object, the vibrating body 110 may be supported so as not to be moved against the reaction force.

In the example and the modifications described above, pairs of the coupling portions 124, 125 and 126 are provided on the both sides of the vibrating body 110 in the Y-direction. However, the coupling portions may be provided only on one side. Accordingly, even when a space for installing the piezoelectric motor 100 is limited, the vibrating body 110 may be supported by coupling the supporting portions 128 to one side of the vibrating body 110.

In the above-described example, the positions for providing the coupling portions are in a symmetric fashion on the both sides of the vibrating body 110 in the Y-direction. However, the coupling portions may be provided in an asymmetric fashion. FIG. 12 is an explanatory drawing illustrating the piezoelectric motor 100 of a sixth modification in which the position where the coupling portions are to be provided are formed to be asymmetry on the both sides of the vibrating body 110 in the Y-direction. As illustrated in the drawing, one of the sides of the vibrating body 110 in the Y-direction is provided with the coupling portions 124 and 126 at the front node portion 116a and the middle node portion 116b, and the other side is provided with the coupling portions 126 and 125 at the middle node portion 116b and the rear node portion 116c.

In the vibrating body 110 of the sixth modification, the rear side portion on one side where the coupling portions 124 and 126 are provided at the front node portion 116a and the middle node portion 116b and the front side portion on the other side where the coupling portions 126 and 125 are provided at the middle node portion 116b and the rear node portion 116c (hatched portions in the drawing) are not constrained by the coupling portions 124, 125 and 126, so that large vibration is allowed. Therefore, by applying a voltage to these portions, the trajectory of the oval movement in one direction (leftward turn in the illustrated example) of the projecting portion 122 may be larger than the trajectory of the oval movement in the other direction. By setting the object adequately so as to match the oval movement having a larger trajectory, a large drive stroke may be ensured. In this manner, by providing the coupling portions at the positions in a asymmetry fashion on the both sides of the vibrating body 110 in the Y-direction and specifying the driving direction of the object to one direction, the object can be driven efficiently.

The piezoelectric motor 100 of the above-described example or the piezoelectric motor 100 of the modifications are capable of enhancing the support of the vibrating body 110 without adversely affecting the driving characteristics of the piezoelectric motor 100. Therefore, the piezoelectric motor 100 may be integrated suitably as a driving unit for the apparatus described below.

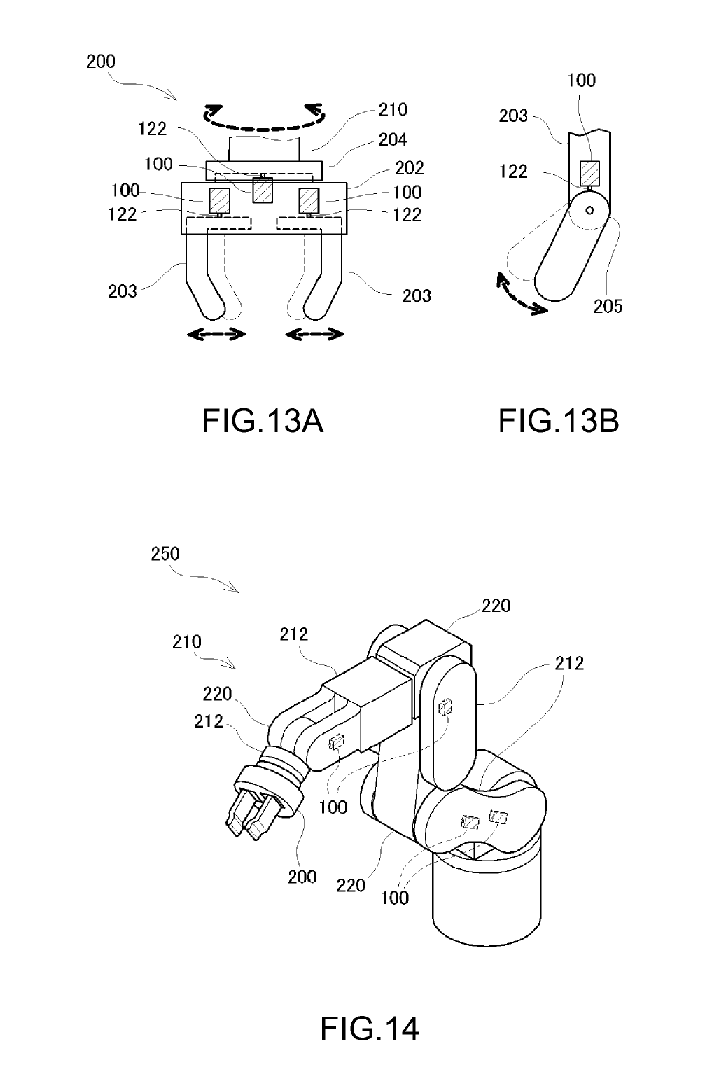

FIGS. 13A and 13B are explanatory drawings exemplifying a robot hand 200 having the piezoelectric motor 100 of the example or the modifications integrated therein. The illustrated robot hand 200 includes a plurality of finger portions 203 extending upright from a base block 202, and is connected to an arm 210 via a wrist 204. Here, as illustrated in FIG. 13A, root portions (movable portions) of the finger portions 203 are movable within the base block 202, and the piezoelectric motors 100 are mounted in a state in which the projecting portions 122 are pressed against the root portions of the finger portions 203. Therefore, by operating the piezoelectric motors 100, the finger portions 203 can be moved for gripping the object. The piezoelectric motors 100 are drive units for moving the finger portions 203. The portion of the wrist 204 is also provided with the piezoelectric motor 100 in a state in which the projecting portion 122 is pressed against an end surface of the wrist 204. Therefore, by operating the piezoelectric motor 100, the entire part of the base block 202 may be rotated.

As illustrated in FIG. 13B, the finger portion 203 is provided with a joint portion 205 for allowing the finger portion 203 to bend. In the joint portion 205 as well, the piezoelectric motor 100 is mounted in a state in which the projecting portion 122 is pressed against a portion for rotating the joint portion 205 (movable portion). Therefore, by operating the piezoelectric motors 100, the finger portions 203 can be bent.

FIG. 14 is an explanatory drawing exemplifying a single arm robot 250 provided with the robot hand 200 (hand portion). As illustrated, the robot 250 includes an arm 210 (arm portion) provided with a plurality of link portions 212 (link member) and joint portions 220 configured to connect the link portions 212 in a bendable state. The robot hand 200 is connected to a distal end of the arm 210. The piezoelectric motors 100 of the example or the modifications are integrated in the joint portions 220 as driving units for bending the joint portions 220, and the projecting portions 122 are pressed against portions to be rotated (movable portions) of the joint portions 220. Therefore, by operating the piezoelectric motors 100, the respective joint portions 220 may be bent (rotated) by given angles.

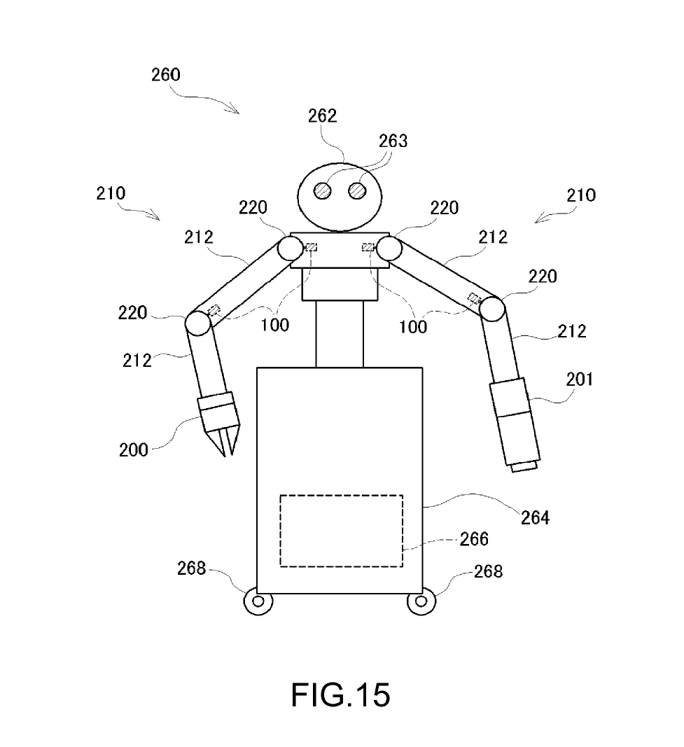

FIG. 15 is an explanatory drawing exemplifying a plural arm robot 260 provided with the robot hand 200. As illustrated, the robot 260 includes a plurality of (two in the illustrated example) the arms 210 provided with a plurality of the link portions 212 and the joint portions 220 configured to connect the link portions 212 in a bendable state. The robot hand 200 and a tool 201 (hand portion) are connected to distal ends of the arms 210. A plurality of cameras 263 are mounted on a head portion 262, and a control unit 266 configured to control the entire operation is mounted in the interior of a body portion 264. In addition, the robot 260 is transportable by wheels 268 provided on a bottom surface of the body portion 264. In this robot 260 as well, the piezoelectric motors 100 of the example or the modifications are integrated in the joint portions 220 as driving units for bending the joint portions 220, and the projecting portions 122 are pressed against portions to be rotated (movable portions) of the joint portions 220. Therefore, by operating the piezoelectric motors 100, the respective joint portions 220 may be bent (rotated) by given angles.

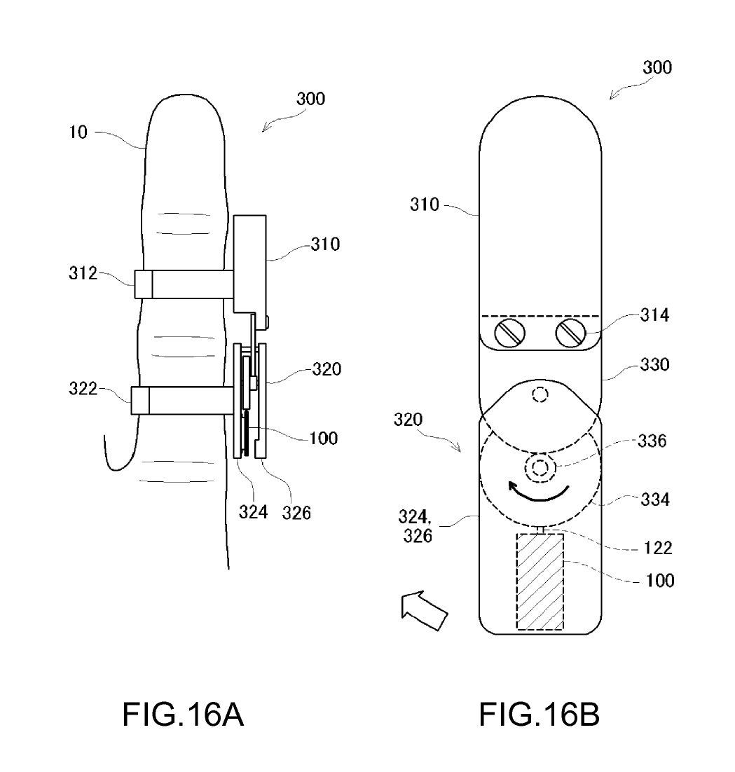

FIGS. 16A and 16B are explanatory drawings exemplifying a finger assist apparatus 300 having the piezoelectric motor 100 of the example or the modification integrated therein. FIG. 16A illustrates a state in which the finger assist apparatus 300 is mounted on a human finger (forefinger) 10 when viewed from the palm side of the finger. As illustrated in the drawing, the finger assist apparatus 300 includes a first unit 310 and a second unit 320 coupled in series. The first unit 310 of this application example corresponds to a “first member” according to the invention, and the second unit 320 of this application example corresponds to a “second member” according to the invention. In the illustrated example, the first unit 310 is mounted on a side surface of a middle knuckle (between the first joint and the second joint) of the forefinger 10 by a first mounting portion 312, and the second unit 320 is mounted on a side surface of a proximal knuckle (between the second joint and the third joint) by a second mounting portion 322.

FIG. 16B is a front view of the finger assist apparatus 300 viewed from a side opposite to a side to be extended along the forefinger 10. The second unit 320 of the finger assist apparatus 300 is provided with an output member 330, which is a metallic flat plate formed into a shape of combination of a square and semicircles, between two frame plates (first frame plate 324 and second frame plate 326) so as to be rotatable about an axis at a center of an arc (see FIG. 16A). The first unit 310 is coupled with a coupling screw 314 on the square side of the output member 330.

a disc-shaped rotor 334 configured to rotate about an axis different from that of the output member 330, a spur gear 336 rotating about the same axis as the rotor 334, and the piezoelectric motor 100 configured to rotate the rotor 334 are provided between the two frame plate 324 and 326. Teeth (not illustrated) engaging the spur gear 336 are formed on an outer periphery of the semi-circular portion of the output member 330, and when the rotor 334 rotates, the rotation is transmitted to the output member 330 at a speed reduced at a predetermined ratio via the spur gear 336, whereby the output member 330 rotates.

The piezoelectric motor 100 is fixed to the first frame plate 324 in a state in which the projecting portion 122 is pressed against an outer peripheral surface of the rotor 334. Therefore, for example, when the piezoelectric motor 100 is driven and the rotor 334 is rotated clockwise on the drawing, the second unit 320 rotates clockwise with respect to the first unit 310 coupled to the output member 330 as indicated by a hollow arrow in the drawing (the first unit 310 rotates counterclockwise with respect to the second unit 320) and is bent. In contrast, when the rotor 334 is rotated counterclockwise, the second unit 320 rotates counterclockwise with respect to the first unit 310 (the first unit 310 rotates clockwise with respect to the second unit 320), and is expanded. In this manner, in the finger assist apparatus 300, the second unit 320 can be bent or stretched with respect to the first unit 310, so that bending and stretching of the second joint of the forefinger 10 is assisted.

The finger assist apparatus 300 in this configuration is capable of assisting persons having a paralyzed finger due to diseases such as cerebral stroke or accident to make his or her finger bend or stretch, or ages persons who has weakened hand grip due to the ages by being worn on a finger. By putting the finger assist apparatus 300 on the finger of the person having a paralyzed finger, it is effective for rehabilitation especially of the action of stretching the finger.

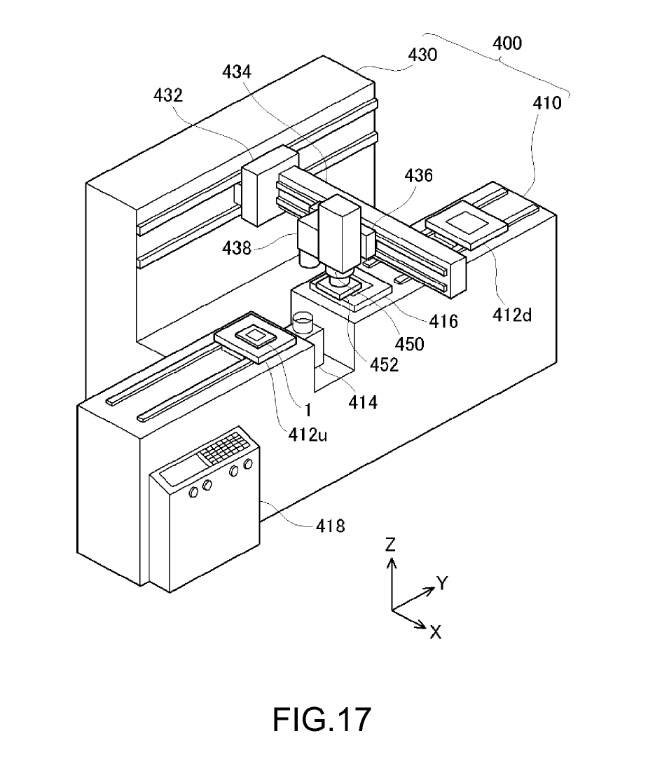

FIG. 17 is a perspective view exemplifying an electronic component inspecting apparatus 400 having the piezoelectric motor 100 of the example or the modification integrated therein. The illustrated electronic component inspecting apparatus 400 roughly includes a base block 410 and a supporting base 430 extending upright from a side surface of the base block 410. The base block 410 is provided with an upstream stage 412u on which an electronic component 1 as an object of inspection is placed and conveyed and a downstream stage 412d on which the electronic component 1 after the inspection are placed and conveyed on an upper surface thereof. Provided between the upstream stage 412u and the downstream stage 412d are an image pickup apparatus 414 for confirming the posture of the electronic component 1, and an inspection bed 416 (inspecting portion) on which the electronic component is set for an inspection of electric characteristics. Representative examples of the electronic component 1 include “semiconductor”, “semiconductor wafer”, “display device such as LCD or OLED”, “crystal device”, “various sensor”, “ink jet head”, and “various MEMS devices”.

The supporting base 430 is provided with a Y stage 432 so as to be movable in a direction parallel to the upstream stage 412u and the downstream stage 412d of the base block 410 (Y-direction), and an arm portion 434 extends from the Y stage 432 in a direction toward the base block 410 (X-direction). An X stage 436 is provided so as to be movable in the X-direction on a side surface of the arm portion 434. The X stage 436 includes an image pickup camera 438, and a gripping device 450 having a Z stage movable in a vertical direction (Z-direction) integrated therein. A gripping portion 452 configured to grip the electronic component 1 is provided at a distal end of the gripping device 450. In addition, a control device 418 configured to control the entire operation of the electronic component inspecting apparatus 400 is provided on a front side of the base block 410. In this example, the Y stage 432 provided on the supporting base 430, the arm portion 434, the X stage 436, and the gripping device 450 corresponds to “electronic component conveying apparatus” according to the invention.

The electronic component inspecting apparatus 400 having the configuration as described above performs the inspection of the electronic component 1 in the following manner. First of all, the electronic component 1 as the object of inspection is placed on the upstream stage 412u and moves to a position near the inspection bed 416. Subsequently, the Y stage 432 and the X stage 436 are moved to move the gripping device 450 to a position right above the electronic component 1 placed on the upstream stage 412u. At this time, the position of the electronic component 1 may be confirmed by using the image pickup camera 438. Subsequently, when the gripping device 450 is moved downward to make the gripping portion 452 grip the electronic component 1 by using the Z stage integrated in the gripping device 450, the gripping device 450 may be moved as is onto the image pickup apparatus 414, and the posture of the electronic component 1 is confirmed by using the image pickup apparatus 414. Subsequently, the posture of the electronic component 1 is adjusted by using a fine-adjustment mechanism integrated in the gripping device 450. Then, the gripping device 450 is moved onto the inspection bed 416, and then the Z stage integrated in the gripping device 450 is moved to set the electronic component 1 on the inspection bed 416. Since the posture of the electronic component 1 is adjusted by using the fine-adjustment mechanism of the gripping device 450, the electronic component 1 can be set to a right position on the inspection bed 416. When the inspection of the electric characteristics of the electronic component 1 is terminated, the electronic component 1 is taken out from the inspection bed 416, then the Y stage 432 and the X stage 436 are moved to move the gripping device 450 to a position above the downstream stage 412d, and then the electronic component 1 is placed on the downstream stage 412d. Subsequently, the downstream stage 412d is moved to convey the electronic component 1 after having inspected to a predetermined position.

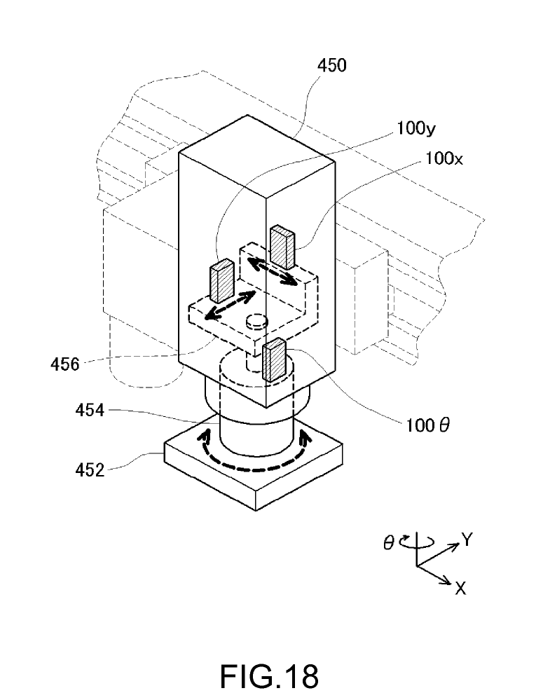

FIG. 18 is an explanatory drawing about the fine-adjustment mechanism integrated in the gripping device 450. As illustrated in the drawing, the gripping device 450 includes a revolving shaft 454 connected to the gripping portion 452 and a fine-adjustment plate 456 (movable portion) rotatably mounted on the revolving shaft 454 provided therein. The fine-adjustment plate 456 is movable in the X-direction and the Y-direction so as to be guided by a guide mechanism, not illustrated.

As illustrated as a hatched portion in FIG. 18, a piezoelectric motor 100θ for the direction of rotation is mounted so as to face an end surface of the revolving shaft 454, and a projecting portion (illustration is omitted) of the piezoelectric motor 100θ is pressed against the end surface of the revolving shaft 454. Therefore, by operating the piezoelectric motor 100θ, the revolving shaft 454 (and the gripping portion 452) can be rotated with high degree of accuracy by a given angle in a e direction. A piezoelectric motor 100x for the X-direction and a piezoelectric motor 100y for the Y-direction are provided so as to face the fine-adjustment plate 456, and respective projecting portions (illustration is omitted) are pressed against the surface of the fine-adjustment plate 456. Therefore, by operating the piezoelectric motor 100x, the fine-adjustment plate 456 (and the gripping portion 452) may be moved with high degree of accuracy by a given distance in the X-direction, and in the same manner, by operating the piezoelectric motor 100y, the fine-adjustment plate 456 (and the gripping portion 452) can be moved in the Y-direction with high degree of accuracy by a given distance. Therefore, the electronic component inspecting apparatus 400 in FIG. 17 is capable of fine-adjusting the posture of the electronic component 1 gripped by the gripping portion 452 by operating the piezoelectric motor 100θ, the piezoelectric motor 100x, and the piezoelectric motor 100y.

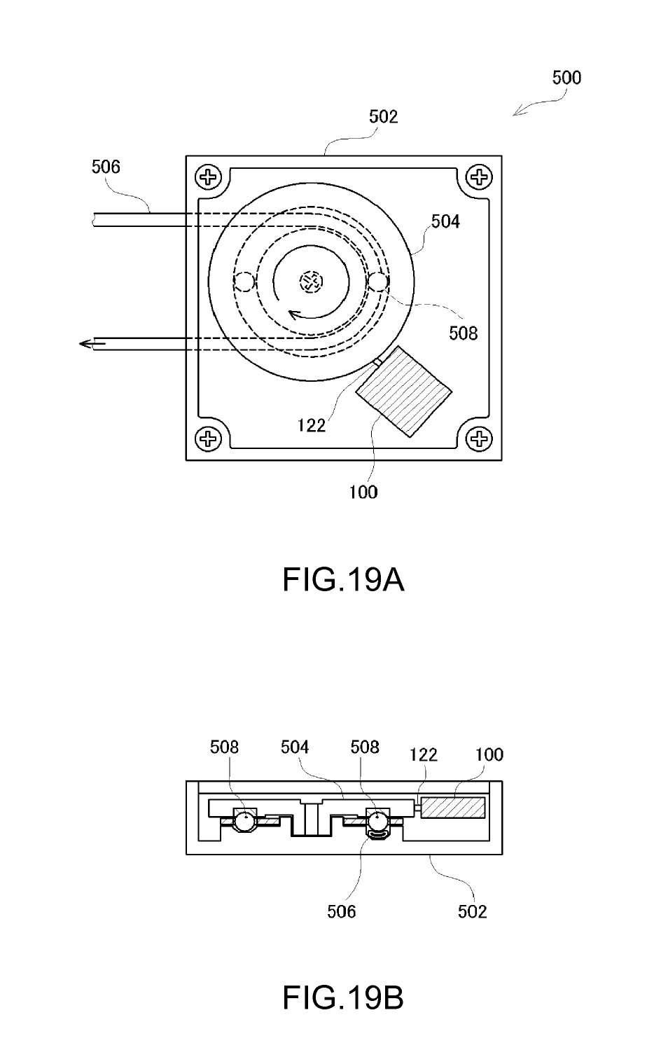

FIGS. 19A and 19B are explanatory drawings exemplifying a liquid feed pump 500 including the piezoelectric motor 100 of the example or the modification integrated therein. FIG. 19A is a plan view of the liquid feed pump 500 viewed from the top, and FIG. 19B is a cross-sectional view of the liquid feed pump 500 viewed from a side. As illustrated in the drawing, the liquid feed pump 500 is provided with a rotor 504 (moving portion) having a disc-shape in the interior of a rectangular-shaped case 502 so as to be rotatable, and a tube 506 configured to allow liquid such as drug solution to flow therein is interposed between the case 502 and the rotor 504. Part of the tube 506 is in a closed state by being collapsed by a ball 508 (closing portion) provided in the rotor 504. Therefore, when the rotor 504 rotates, a point where the ball 508 collapses the tube 506 moves, so that the liquid in the tube 506 is fed. If the projecting portion 122 of the piezoelectric motor 100 is provided in the state of being pressed against an outer peripheral surface of the rotor 504, the piezoelectric motor 100 may be used as a drive unit for driving the rotor 504. In this configuration, a very slight amount of liquid can be fed with high degree of accuracy and, in addition, a compact liquid feed pump 500 may be realized.

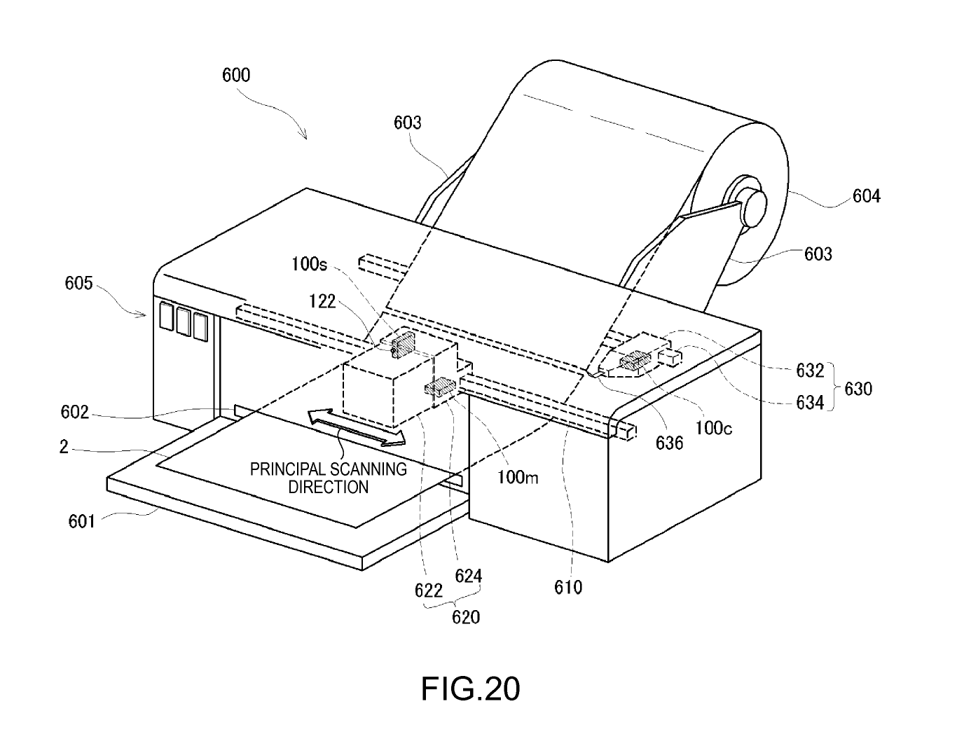

FIG. 20 is a perspective view exemplifying a printing apparatus 600 having the piezoelectric motor 100 of the example or the modifications integrated therein. The illustrated printing apparatus 600 is a so-called inkjet printer configured to print an image by ejecting ink onto a surface of a printing medium 2. An “image” printed by the printing apparatus 600 includes characters, graphics, pictures, patterns, and photographic images. The printing apparatus 600 has a substantially box-shaped appearance, and includes a paper discharge tray 601, a discharge port 602, and a plurality of operation buttons 605 provided at a substantially center of a front surface. A supply tray 603 is provided on the back side. If the printing medium 2 is set on the supply tray 603 and the operation button 605 is operated, the printing medium 2 is introduced from the supply tray 603 into the printing apparatus 600, an image is printed on the surface of the printing medium 2 in the interior of the printing apparatus 600, and then the printing medium 2 is discharged from the discharge port 602.

Provided in the interior of the printing apparatus 600 are a printhead 620 configured to reciprocate in a primary scanning direction on the printing medium 2, and a guide rail 610 configured to guide the movement of the printhead 620 in the primary scanning direction. The illustrated printhead 620 includes a printing portion 622 configured to eject ink on the printing medium 2, and a scanning portion 624 configured to cause the printhead 620 to scan in the primary scanning direction. A plurality of ejection nozzles are provided on a bottom surface side of the printing portion 622 (a side facing the printing medium 2), and ink may be ejected from the ejection nozzles toward the printing medium 2. The scanning portion 624 is provided with piezoelectric motors 100m and 100s as drive units mounted thereon. The projecting portion (illustration is omitted) of the piezoelectric motor 100m is pressed against the guide rail 610. Therefore, by operating the piezoelectric motor 100m, the printhead 620 may be moved in the primary scanning direction. The projecting portion 122 of the piezoelectric motor 100s is pressed against the printing portion 622. Therefore, by operating the piezoelectric motor 100s, the bottom surface side of the printing portion 622 can be brought toward and away from the printing medium 2. The printing apparatus 600 also includes a cutting mechanism 630 configured to cut a roll paper 604 mounted thereon. The cutting mechanism 630 includes a cutter holder 632 having a paper cutter 636 mounted on a distal end thereof, and a guide shaft 634 configured to extend in the primary scanning direction so as to penetrate through the cutter holder 632. A piezoelectric motor 100c is mounted in the cutter holder 632, and a projecting portion, not illustrated, of the piezoelectric motor 100c is pressed against the guide shaft 634. Therefore, when the piezoelectric motor 100c is operated, the cutter holder 632 moves in the primary scanning direction along the guide shaft 634, and the paper cutter 636 cuts the roll paper 604. The piezoelectric motor 100 can be used as the drive unit for feeding the printing medium 2.

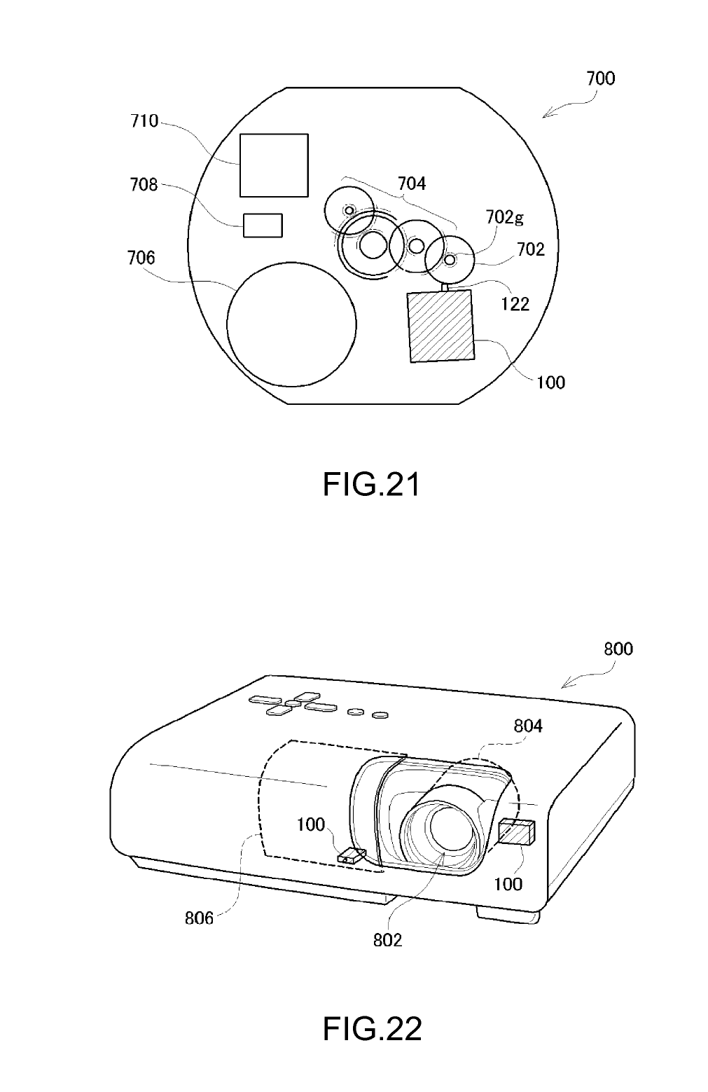

FIG. 21 is an explanatory drawing exemplifying an internal structure of an electronic timepiece 700 having the piezoelectric motor 100 of the example or the modifications integrated therein. FIG. 21 is a plan view of the electronic timepiece 700 when viewed from a side (back lid side) opposite from a time indicating side. The electronic timepiece 700 exemplified in FIG. 21 includes a disc-shaped rotary disc 702, a gear train 704 configured to transmit the rotation of the rotary disc 702 to a hand (illustration is omitted) for indicating time of day, the piezoelectric motor 100 as a drive unit configured to drive the rotary disc 702, a power supply unit 706, a crystal tip 708, and an IC 710. The power supply unit 706, the crystal tip 708, and the IC 710 are mounted on a circuit board, not illustrated. The gear train 704 is composed of a plurality of gears including a ratchet (not illustrated), and adjacent gears engage each other with teeth so as to transmit the rotations thereof in sequence. In order not to make the illustration complicated, addendum circles of the gears are indicated by thin chain lines, and dedendum circles of the gears are indicated by thick solid lines in FIG. 21. Therefore, the double circles including the thick solid line and the thin chain line indicate gears. The thin chain lines, which indicate the addendum are not illustrated over the entire circumferences, and only peripheries of portions engaging other gears are illustrated.

The rotary disc 702 is provided with a coaxial small gear 702g, and the gear 702g engages the gear train 704. Therefore, the rotation of the rotary disc 702 is transmitted to the gear train 704 while being reduced in speed at a predetermined ratio. The rotation of the gear is transmitted to the hand which indicates time of day to indicate time of day. If the projecting portion 122 of the piezoelectric motor 100 is provided in a state of being pressed against an outer peripheral surface of the rotary disc 702, the piezoelectric motor 100 can be used as a drive unit for driving the rotary disc 702.

FIG. 22 is an explanatory drawing exemplifying a projection apparatus 800 having the piezoelectric motor 100 of the example or the modifications integrated therein. As illustrated, the projection apparatus 800 is provided with a projecting portion 802 including optical lenses, and is configured to display an image by projecting light from a light source (illustration is omitted) integrated therein. An adjusting mechanism 804 (adjusting portion) for adjusting a focal point of the optical lenses included in the projecting portion 802 may be driven by using the piezoelectric motor 100 as the drive unit. The piezoelectric motor 100 has a high resolution capability for positioning, and hence a minute focal point adjustment is possible. While the light is not projected from the light source, the optical lenses of the projecting portion 802 may be prevented from being scratched by being covered with a lens cover 806. The piezoelectric motor 100 may also be used as a drive unit for opening and closing the lens cover 806.

The piezoelectric motor and various devices and apparatus having the piezoelectric motor mounted thereon have been described. However, the invention is not limited to the example, the modifications, and application examples, and may be implemented in various modes without departing the gist of the invention.

For example, in the example and the modifications, the mode in which the reinforcing member 140 is provided in tight contact with the supporting portions 128, the mode in which the supporting portions 128 are bent, the mode in which the thickness of the supporting portion 128 is set to be thicker than the shim plate 120, and the mode in which the supporting portions 128 are formed of a material (including the vibration damping material) having a higher rigidity than that of the shim plate 120 have been employed in order to set the rigidity of the supporting portions 128 to be higher than that of the shim plate 120. However, two or more of these modes may be combined. In this configuration, the rigidity of the supporting portions 128 may further be enhanced.

The entire disclosure of Japanese Patent Application No. 2013-252753, filed Dec. 6, 2013 is expressly incorporated by reference herein.

What is claimed is:

1. A piezoelectric motor comprising:
a vibrating body capable of generating a bending vibration;
a joint portion to which the vibrating body is joined;
a supporting portion disposed in parallel to the joint portion and configured to support the vibrating body and the joint portion; and
a plurality of coupling portions configured to couple the joint portion and the supporting portion, wherein
the supporting portion has rigidity higher than that of the joint portion.

2. The piezoelectric motor according to claim 1, further comprising:
a reinforcing member for enhancing rigidity of the supporting portion.

3. The piezoelectric motor according to claim 2, wherein
the reinforcing member includes a vibration damping material.

4. The piezoelectric motor according to claim 1, wherein
the supporting portion includes a bent portion formed by being bent along a segment intersecting a direction in which the vibrating body is bent.

5. The piezoelectric motor according to claim 1, wherein
the supporting portion has a thickness larger than that of the joint portion.

6. The piezoelectric motor according to claim 1, wherein
the supporting portion is formed of a material having rigidity higher than that of the joint portion.

7. The piezoelectric motor according to claim 1, wherein
the joint portion, the supporting portion, and the coupling portions are formed integrally from a single plate member.

8. The piezoelectric motor according to claim 7, comprising:
a leaf spring configured to bias the vibrating body toward an object driven by the piezoelectric motor, wherein
the leaf spring is formed integrally with the joint portion, the supporting portion, and the coupling portion by bending a single plate member.

9. The piezoelectric motor according to claim 8, further comprising:
a fixing portion configured to fix the piezoelectric motor at a predetermined position, wherein
the fixing portion is formed integrally with the joint portion, the supporting portion, the coupling portions, and the leaf spring by bending a single plate member.

10. The piezoelectric motor according to claim 1, wherein
the vibrating body is provided with a front node portion closer to the object, a rear node portion farther from the object, and a middle node portion between the front node portion and the rear node portion as node portions having an amplitude of the bending vibration smaller than that of an end portion on a side abutting against the object that the piezoelectric motor drives, and
the coupling portions are provided at selected two or more of the front node portion, the middle node portion, and the rear node portion.

11. A robot hand configured to be capable of grasping an object with a finger portion, comprising:
a base member having the finger portion extending upright so as to be movable;
a movable portion interlocked with a movement of the finger portion or a rotation of joints of the finger portion with respect to the base member;
a vibrating body capable of generating a bending vibration;
an abutting portion configured to abut against the movable portion and drive the movable portion by transmitting the vibration of the vibrating body;
a joint portion to which the vibrating body is joined;
a supporting portion disposed in parallel to the joint portion and configured to support the vibrating body and the joint portion; and
a plurality of coupling portions configured to couple the joint portion and the supporting portion, wherein
the supporting portion has rigidity higher than that of the joint portion.

12. A robot comprising:
an arm portion provided with a rotatable joint portion;
a hand portion provided on the arm portion; and
a body portion provided with the arm portion;
a movable portion interlocked with a rotation of the joint portion;
a vibrating body capable of generating a bending vibration;
an abutting portion configured to abut against the movable portion and drive the movable portion by transmitting the vibration of the vibrating body;
a joint portion to which the vibrating body is joined;
a supporting portion disposed in parallel to the joint portion and configured to support the vibrating body and the joint portion; and
a plurality of coupling portions configured to couple the joint portion and the supporting portion, wherein
the supporting portion has rigidity higher than that of the joint portion.
